(19) United States
(12) Patent Application Publication
(10) Pub. No.: US 2026/0334129 A1
(43) Pub. Date: Oct. 22, 2026

(54) SUBSTRATE PROCESSING APPARATUS AND SUBSTRATE PROCESSING METHOD

(71) Applicant: Tokyo Electron Limited, Tokyo (JP)

(72) Inventors: Yosuke KAWABUCHI, Koshi City, Kumamoto (JP); Naoya MIYAMOTO, Koshi City, Kumamoto (JP)

(73) Assignee: Tokyo Electron Limited, Tokyo (JP)

(21) Appl. No.: 19/107,581

(22) PCT Filed: Aug. 18, 2023
(86) PCT No.: PCT/JP2023/029779

§ 371 Date: Feb. 28, 2025

(30) Foreign Application Priority Data
Sep. 1, 2022 (JP) 2022-139192

(51) Int. Cl. H10P 72/00; G01B 21/20; H10P 70/00

(52) U.S. Cl. CPC H10P 72/0406; H10P 70/60; G01B 21/20

(57) ABSTRACT

A substrate processing apparatus includes a processing vessel; a substrate holder, disposed within the processing vessel, for holding a substrate; a gas nozzle for jetting a gas to an inside of the processing vessel; an adjusting mechanism for adjusting a distance between the substrate held by the substrate holder and the gas nozzle; and a controller. The controller sets a target value of the distance based on a flow state of the gas jetted from the gas nozzle, and controls the adjusting mechanism such that the distance becomes the target value.

### TECHNICAL FIELD

The various aspects and embodiments described herein pertain generally to a substrate processing apparatus and a substrate processing method.

### BACKGROUND

There is known a technique of removing particles adhering to a substrate by allowing a normal shock wave generated by jetting a gas from a gas nozzle to collide with the substrate (see, for example, Patent Document 1).

### PRIOR ART DOCUMENT

Patent Document 1: International Publication No. 2020/110858

### DISCLOSURE OF THE INVENTION

### Problems to Be Solved by the Invention

Exemplary embodiments provide a technique capable of removing particles efficiently according to a processing environment.

### Means for Solving the Problems

In an exemplary embodiment, a substrate processing apparatus includes a processing vessel; a substrate holder disposed within the processing vessel, and configured to hold a substrate; a gas nozzle configured to jet a gas to an inside of the processing vessel; an adjusting mechanism configured to adjust a distance between the substrate held by the substrate holder and the gas nozzle; and a controller. The controller is configured to set a target value of the distance based on a flow state of the gas jetted from the gas nozzle, and to control the adjusting mechanism such that the distance becomes the target value.

### Effect of the Invention

According to the exemplary embodiment, it is possible to remove the particles efficiently according to the processing environment.

### BRIEF DESCRIPTION OF THE DRAWINGS

FIG. 1 is a schematic diagram illustrating a substrate processing apparatus according to an exemplary embodiment.

FIG. 2 is a cross sectional view illustrating collision of a normal shock wave with a substrate according to the exemplary embodiment.

FIG. 3 is a diagram illustrating an example of a distance adjusting method according to the exemplary embodiment.

FIG. 4 is a flowchart showing a substrate processing method according to the exemplary embodiment.

### DETAILED DESCRIPTION

Hereinafter, non-limiting illustrative exemplary embodiments of the present disclosure will be described with reference to the accompanying drawings. In the various drawings, same or corresponding members or parts will be assigned same or corresponding reference numerals, and redundant descriptions thereof will be omitted.

In the following description, the X-axis, Y-axis and Z-axis directions are mutually orthogonal directions, and the X-axis and Y-axis directions are horizontal directions, whereas the Z-axis direction is a vertical direction. Further, “downwards” means vertically downwards (negative Z-axis direction), and “upwards” means vertically upwards (positive Z-axis direction).

### Substrate Processing Apparatus

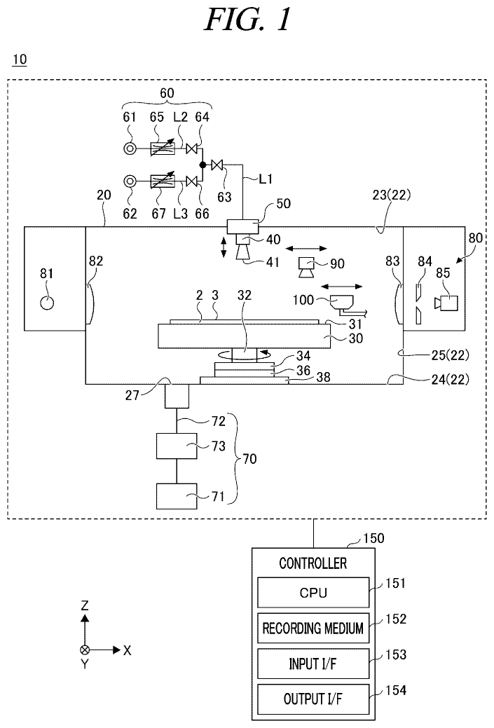

Referring to FIG. 1 to FIG. 3, a substrate processing apparatus according to an exemplary embodiment will be explained. FIG. 1 is a schematic diagram illustrating the substrate processing apparatus according to the exemplary embodiment.

A substrate processing apparatus 10 is configured to remove particles adhering to a main surface 3 of a substrate 2 by jetting a gas toward the main surface 3 of the substrate 2. The substrate 2 is, for example, a semiconductor substrate such as a silicon wafer. The substrate processing apparatus 10 is mainly equipped with a processing vessel 20, a substrate holder 30, a rotation shaft 32, a rotation driver 34, an elevation driver 36, a horizontal driver 38, a gas nozzle 40, a nozzle elevation driver 50, a gas supply mechanism 60, a decompression mechanism 70, a Schlieren device 80, a distance measurer 90, a gas receiver 100, and a controller 150.

The processing vessel 20 has therein a space in which the substrate 2 is to be processed. The processing vessel 20 also has a carry-in/out opening (not shown) for the substrate 2, and a gate valve (not shown) for opening and closing the carry-in/out opening. An inner wall surface 22 of the processing vessel 20 includes an upper wall surface 23, a lower wall surface 24, and a sidewall surface 25 that extends from an outer periphery of the upper wall surface 23 to an outer periphery of the lower wall surface 24.

The substrate holder 30 is disposed inside the processing vessel 20. The substrate holder 30 has a substrate holding surface 31 configured to hold the substrate 2. For example, the substrate holder 30 holds the substrate 2 horizontally with the main surface 3 of the substrate 2, from which particles are to be removed, facing upwards. The substrate holder 30 may include an electrostatic chuck. In this case, since the substrate 2 held on the substrate holding surface 31 can be fixed by being electrostatically attracted, bending or misalignment of the substrate 2 on the substrate holding surface 31 can be suppressed. The substrate holder 30 may include a mechanical clamp. In this case, since the substrate 2 held on the substrate holding surface 31 can be fixed by being mechanically pressed down, the bending or the misalignment of the substrate 2 on the substrate holding surface 31 can be suppressed.

The rotation shaft 32 extends downwards from the center of the substrate holder 30 and is vertically arranged.

The rotation driver 34 is configured to rotate the substrate holder 30 by rotating the rotation shaft 32 around a vertical axis. The rotation driver 34 has, by way of example, a turning motor, and a transmission mechanism configured to transmit a rotational driving force of the turning motor to the rotation shaft 32.

The elevation driver 36 is configured to move the substrate holder 30 up and down. The elevation driver 36 is composed of, by way of example, a fluid pressure cylinder, or the like. The elevation driver 36 moves the substrate holder 30 up and down via, for example, the rotation driver 34. However, the elevation driver 36 may elevate the substrate holder 30 up and down without the rotation driver 34 therebetween. The elevation driver 36 is an example of an adjusting mechanism.

The horizontal driver 38 is configured to move the substrate holder 30 in a horizontal direction perpendicular to a center line of the rotation shaft 32, thus allowing the gas nozzle 40 and the substrate holder 30 to be moved relative to each other in a radial direction of the substrate 2. The horizontal driver 38 moves the substrate holder 30 along a guide rail, for example. Alternatively, the horizontal driver 38 may move the substrate holder 30 by turning an arm.

The gas nozzle 40 is configured to jet a gas toward the main surface 3 of the substrate 2 held by the substrate holder 30. The gas nozzle 40 is disposed above the substrate holder 30 with its injection opening 41 for the gas facing downwards. The gas nozzle 40 is mounted to the nozzle elevation driver 50.

The nozzle elevation driver 50 is configured to move the gas nozzle 40 up and down. The nozzle elevation driver 50 is composed of, by way of example, a fluid pressure cylinder, or the like. As another example, the nozzle elevation driver 50 may be composed of an electric motor, and a ball screw configured to convert a rotating motion of the electric motor into an elevating motion of the gas nozzle 40. The nozzle elevation driver 50 is provided on the upper wall surface 23 of the processing vessel 20. The nozzle elevation driver 50 is an example of the adjusting mechanism.

The gas supply mechanism 60 is configured to supply a gas to the gas nozzle 40. The gas supply mechanism 60 has a common line L1 whose downstream end is connected to the gas nozzle 40, a first branch line L2 extending from an upstream end of the common line L1 to a first source 61, and a second branch line L3 extending from the upstream end of the common line L1 to a second source 62.

The common line L1 is provided with a pressure regulating valve 63 configured to regulate a supply pressure P of the gas to the gas nozzle 40. The pressure regulating valve 63 is configured to regulate the supply pressure P of the gas to the gas nozzle 40 under the control of the controller 150. The common line L1 may be further provided with a booster such as a gas booster upstream of the pressure regulating valve 63.

The first branch line L2 is provided with a first opening/closing valve 64 and a first flow rate regulating valve 65. When the first opening/closing valve 64 opens a flow path for a gas, the gas is supplied from the first source 61 to the gas nozzle 40. The first flow rate regulating valve 65 is configured to regulate the flow rate of the gas flowing through the first branch line L2. When the first opening/closing valve 64 closes the flow path for the gas, the supply of the gas from the first source 61 to the gas nozzle 40 is stopped.

The second branch line L3 is provided with a second opening/closing valve 66 and a second flow rate regulating valve 67. When the second opening/closing valve 66 opens a flow path for a gas, the gas is supplied from the second source 62 to the gas nozzle 40. The second flow rate regulating valve 67 is configured to regulate the flow rate of the gas flowing through the second branch line L3. When the second opening/closing valve 66 closes the flow path for the gas, the supply of the gas from the second source 62 to the gas nozzle 40 is stopped.

The first source 61 is configured to supply, for example, a carbon dioxide (CO₂) gas to the gas nozzle 40. The second source 62 is configured to supply, for example, a hydrogen (H₂) gas to the gas nozzle 40. A content C of the carbon dioxide gas included in the gas supplied to the gas nozzle 40 is adjusted by the first flow rate regulating valve 65 and the second flow rate regulating valve 67. The first flow rate regulating valve 65 and the second flow rate regulating valve 67 adjust the content C of the carbon dioxide gas under the control of the controller 150.

The decompression mechanism 70 is configured to decompress the inside of the processing vessel 20. The decompression mechanism 70 has a suction pump 71, a suction line 72, and a pressure regulating valve 73. The suction pump 71 is configured to suck in a gas in the processing vessel 20. The suction line 72 extends from a suction opening 27 formed in the lower wall surface 24 of the processing vessel 20 to the suction pump 71. The pressure regulating valve 73 is provided in a portion of the suction line 72.

The Schlieren device 80 is configured to generate an image (hereinafter referred to as “Schlieren image”) that visualizes the gas jetted from the gas nozzle 40 by a Schlieren method. The Schlieren device 80 has a light source 81, a first Schlieren lens 82, a second Schlieren lens 83, a knife edge 84, and an imaging device 85. The light source 81, the knife edge 84, and the imaging device 85 are disposed outside the processing vessel 20, for example. However, the light source 81, the knife edge 84, and the imaging device 85 may be disposed inside the processing vessel 20. The first Schlieren lens 82 and the second Schlieren lens 83 are provided on the sidewall surface 25 of the processing vessel 20, for example. The first Schlieren lens 82 and the second Schlieren lens 83 are disposed so as to face each other with the gas nozzle 40 therebetween.

Light from the light source 81 is collimated by the first Schlieren lens 82, passes through the gas jetted from the gas nozzle 40, and is focused by the second Schlieren lens 83. The focused light passes through the knife edge 84 and reaches the imaging device 85. The imaging device 85 images the light having passed through the knife edge 84, and transmits the obtained image to the controller 150. At this time, if there is unevenness in the refractive index of the gas jetted from the gas nozzle 40, the light is distorted and gets out of focus, so that the unevenness blocked by the knife edge 84 is displayed as a shadow in the image. As a result, a pressure distribution and a mass flux density distribution of the gas jetted from the gas nozzle 40 are observed as a contrast between light and shade. By way of example, with a rise of the pressure or mass flux density of the gas, the color changes from white to black in the Schlieren image. The light source 81 is, by way non-limiting example, a point light source. The imaging device 85 is, for example, a camera.

The distance measurer 90 is disposed above the substrate holder 30. The distance measurer 90 is configured to detect a distance from the distance measurer 90 to the main surface 3 of the substrate 2. The distance measurer 90 detects the distance from the distance measurer 90 to the main surface 3 of the substrate 2 while moving along the main surface 3 of the substrate 2, for example. In this case, the shape of the substrate 2, such as the bending of the substrate 2, can be detected. The distance measurer 90 is configured to be movable between a position directly above a central portion of the substrate holder 30 and a position directly above an outer periphery of the substrate holder 30. The distance measurer 90 transmits a detection value to the controller 150. The distance measurer 90 may be, by way of non-limiting example, a laser displacement meter. The distance measurer 90 is an example of a detector.

The gas receiver 100 is provided inside the processing vessel 20. The gas receiver 100 is configured to be movable between a gas receiving position below the injection opening 41 and a retreat position near the sidewall surface 25. At the gas receiving position, the gas receiver 100 receives the gas injected from the gas nozzle 40, suppressing the gas from being jetted to the main surface 3 of the substrate 2. The gas receiver 100 is configured to exhaust the received gas to the outside of the processing vessel 20.

The controller 150 is composed of, for example, a computer. The controller 150 is equipped with a CPU (Central Processing Unit) 151 and a recording medium 152 such as a memory. The recording medium 152 stores therein a program that controls various processes performed in the substrate processing apparatus 10. The controller 150 controls the operation of the substrate processing apparatus 10 by causing the CPU 151 to execute the program stored in the recording medium 152. The controller 150 includes an input interface 153 and an output interface 154. The controller 150 receives a signal from the outside through the input interface 153, and transmits a signal to the outside through the output interface 154.

The program may be stored in a computer-readable recording medium, and may be installed from that recording medium into the recording medium 152 of the controller 150. The computer-readable recording medium may be, by way of non-limiting example, a hard disk (HD), a flexible disk (FD), a compact disk (CD), a magnet optical disk (MO), a memory card, or the like. The program may be downloaded from a server via the Internet and installed in the recording medium 152 of the controller 150.

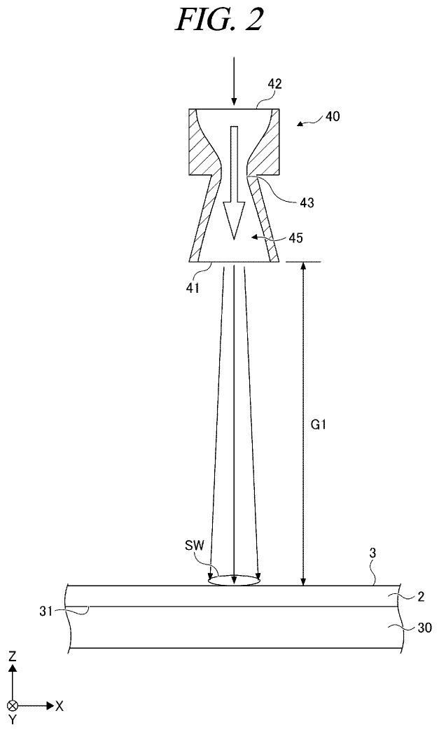

FIG. 2 is a cross sectional view illustrating collision of a normal shock wave with a substrate according to the exemplary embodiment. The gas nozzle 40 is, for example, what is generally called a Laval nozzle. The gas nozzle 40 has the injection opening 41, a supply opening 42, a throat 43, and a tapered hole 45. The throat 43 has a smaller diameter than the supply opening 42. The tapered hole 45 is provided between the throat 43 and the injection opening 41. The diameter of the tapered hole 45 increases as it goes from the throat 43 to the injection opening 41.

The gas nozzle 40 is placed inside the processing vessel 20. The inside of the processing vessel 20 is decompressed by the decompression mechanism 70 in advance. The gas supplied to the supply opening 42 of the gas nozzle 40 is accelerated to a speed exceeding the speed of sound when it passes through the throat 43, and is then jetted from the injection opening 41. The jetted gas forms a normal shock wave SW. The normal shock wave SW is also called a Mach disk. The normal shock wave SW is a shock wave having a wavefront perpendicular to a propagation direction thereof. The shock wave is a discontinuous variation of a pressure that propagates inside the processing vessel 20 at a supersonic speed.

The controller 150 controls the collision of the gas with the substrate 2 held by the substrate holder 30. The collision of the gas with the substrate 2 varies depending on, for example, a distance G1 between the injection opening 41 of the gas nozzle 40 and the main surface 3 of the substrate 2.

Therefore, the controller 150 controls the collision of the gas with the substrate 2 by adjusting the distance G1. The controller 150 adjusts the distance G1 by controlling, for example, the elevation driver 36 to move the substrate holder 30 up and down. Alternatively, the controller 150 may adjust the distance G1 by controlling the nozzle elevation driver 50 to move the gas nozzle 40 up and down. Still alternatively, the controller 150 may adjust the distance G1 by controlling both the elevation driver 36 and the nozzle elevation driver 50 to move both the substrate holder 30 and the gas nozzle 40 up and down.

The controller 150 causes the normal shock wave SW generated by the injection of the gas to collide with the main surface 3 of the substrate 2. In this case, since the normal shock wave SW acts on the main surface 3 of the substrate 2, it is easy to efficiently remove particles attached to the main surface 3 of the substrate 2.

A center line of the gas nozzle 40 may be disposed perpendicular to the main surface 3 of the substrate 2. The wavefront of the normal shock wave SW collides parallel to the main surface 3 of the substrate 2. In this case, the range in which the normal shock wave SW acts on the main surface 3 of the substrate 2 is large, so that the particles can be easily removed. Also, collapse of an irregularity pattern on the main surface 3 of the substrate 2 can be suppressed.

The controller 150 sets a target value of the distance G1 between the injection opening 41 of the gas nozzle 40 and the main surface 3 of the substrate 2 based on a flow state of the gas injected from the gas nozzle 40.

In one exemplary embodiment, the controller 150 sets the target value of the distance G1 based on a pressure distribution of the gas or a mass flux density distribution of the gas calculated by a simulation using environmental parameters. The environmental parameters include parameters that affect the flow state of the gas. The environmental parameters include, by way of example, the content C of the carbon dioxide included in the gas, the pressure of the gas, the flow velocity of the gas, the temperature of the gas, the internal pressure of the processing vessel 20, and the internal temperature of the processing vessel 20. The pressure distribution of the gas and the mass flux density distribution of the gas are examples of the flow state of the gas. The controller 150 sets the target value of the distance G1 so that the main surface 3 of the substrate 2 is located at a position where the pressure of the gas is high or a position where the mass flux density of the gas is high. In this case, since the normal shock wave SW collides with the main surface 3 of the substrate 2, it is easy to efficiently remove the particles adhering to the main surface 3 of the substrate 2.

In one exemplary embodiment, the controller 150 sets the target value of the distance G1 based on a Schlieren image obtained by imaging the gas injected from the gas nozzle 40 with the Schlieren device 80. The Schlieren image is an example of the flow state of the gas. By way of example, the controller 150 analyzes the Schlieren image to identify a position Z1 of the normal shock wave SW, and sets the target value of the distance G1 based on the identified position Z1 of the normal shock wave SW. The controller 150 may generate an image that visualizes the gas injected from the gas nozzle 40, using a device other than the Schlieren device 80.

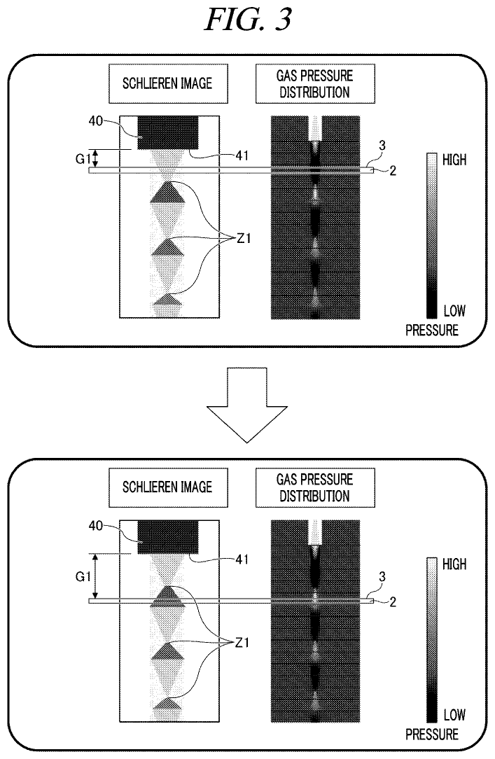

FIG. 3 illustrates an example of a distance adjusting method according to the exemplary embodiment. The upper drawing of FIG. 3 shows a positional relationship between the substrate 2 and the gas nozzle 40 when the distance G1 is not the target value. The lower drawing of FIG. 3 shows a positional relationship between the substrate 2 and the gas nozzle 40 when the distance G1 is the target value. In each of the upper and lower drawings of FIG. 3, the left image illustrates a Schlieren image, and the right image shows a pressure distribution of a gas. As shown in the upper and lower drawings of FIG. 3, with a rise of the pressure of the gas, the color changes from white to black in the Schlieren image.

For example, as illustrated in the upper drawing of FIG. 3, when the main surface 3 of the substrate 2 is located closer to the injection opening 41 than the position Z1 of the normal shock wave SW that is located closest to the injection opening 41 among the multiple specific positions Z1 of the normal shock waves SW, the controller 150 adjusts the distance G1.

As an example, as shown in the lower drawing of FIG. 3, the controller 150 sets the target value of the distance G1 so that the main surface 3 of the substrate 2 is located slightly farther than the position Z1 of the normal shock wave SW that is located closest to the injection opening 41. In this case, since the normal shock wave SW collides with the main surface 3 of the substrate 2, the particles adhering to the main surface 3 of the substrate 2 can be easily and efficiently removed.

As another example, the controller 150 may set the target value of the distance G1 so that the main surface 3 of the substrate 2 is located slightly farther than the normal shock wave SW that is formed at a position farther away from the injection opening 41 than the normal shock wave SW closest to the injection opening 41.

When performing a processing by using a gas cluster, by placing the substrate 2 at or near a position where the normal shock wave SW is generated, the substrate 2 can be irradiated with a gas having higher energy, so that particles can be removed efficiently. The gas cluster is, for example, a collection of carbon dioxide gas molecules bonded together by a van der Waals force. When the gas cluster collides with the main surface 3 of the substrate 2, particles with a small size (e.g., tens of nanometers) adhering to the main surface 3 of the substrate 2 can be removed efficiently.

The collision of the gas with the substrate 2 is also affected by, for example, the content C of the carbon dioxide gas included in the gas supplied to the gas nozzle 40, the supply pressure P of the gas to the gas nozzle 40, and so forth.

Therefore, the controller 150 may control the collision of the gas with the substrate 2 by controlling the content C or the supply pressure P of the carbon dioxide gas.

The composition of the gas supplied to the gas nozzle 40 (for example, the content C of the carbon dioxide gas) is adjusted by, for example, the first flow rate regulating valve 65 and the second flow rate regulating valve 67. The gas supplied to the gas nozzle 40 may include a carbon dioxide gas. As the carbon dioxide gas has a larger molecular weight than a hydrogen gas, its mass flux density is large. The gas supplied to the gas nozzle 40 may include a hydrogen gas. Including the hydrogen gas makes it easy to suppress stalling of the gas cluster. The supply pressure P of the gas supplied to the gas nozzle 40 is adjusted by the pressure regulating valve 63.

According to the substrate processing apparatus 10 described above, the controller 150 sets the target value of the distance G1 based on the flow state of the gas jetted from the gas nozzle 40, and controls at least one of the elevation driver 36 and the nozzle elevation driver 50 so that the distance G1 becomes the target value. This allows particles to be efficiently removed according to the processing environment.

### Substrate Processing Method

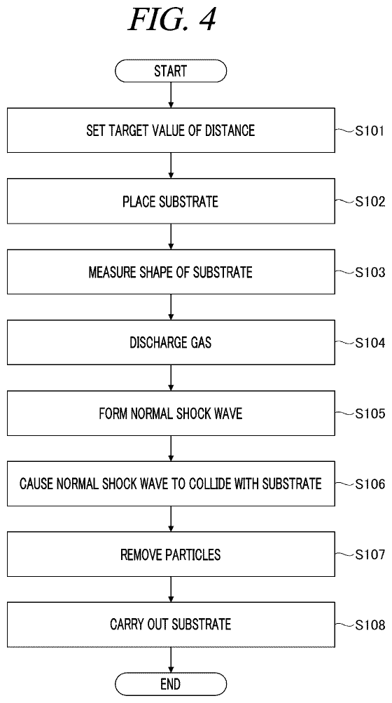

Referring to FIG. 4, a substrate processing method according to the exemplary embodiment will be described. FIG. 4 is a flowchart showing the substrate processing method according to the exemplary embodiment. Processes S101 to S108 shown in FIG. 4 are performed under the control of the controller 150. In one exemplary embodiment, the processes S101 to S108 are performed in this order.

In the process S101, a target value of the distance G1 between the injection opening 41 of the gas nozzle 40 and the main surface 3 of the substrate 2 is set. In the process S101, the controller 150 sets the target value of the distance G1 between the injection opening 41 of the gas nozzle 40 and the main surface 3 of the substrate 2 based on a flow state of the gas jetted from the gas nozzle 40. The process S101 is performed when the substrate 2 is not held by the substrate holder 30, for example.

In one exemplary embodiment, the controller 150 sets the target value of the distance G1 based on a pressure distribution of the gas or a mass flux density distribution of the gas calculated by a simulation using environmental parameters. In one embodiment, the controller 150 sets the target value of the distance G1 based on the Schlieren image obtained by imaging the gas jetted from the gas nozzle 40 with the Schlieren device 80.

In the process S102, the substrate 2 is placed in the processing vessel 20. In the process S102, a transfer device carries the substrate 2 into the processing vessel 20 from the outside of the processing vessel 20, and places the carried substrate 2 on the substrate holding surface 31 of the substrate holder 30. The substrate holder 30 holds the substrate 2 horizontally with the main surface 3 of the substrate 2 facing upwards.

In the process S103, the shape of the substrate 2 held by the substrate holder 30 is detected. In the process S103, the distance measurer 90 detects the distance from the distance measurer 90 to the main surface 3 of the substrate 2. By way of example, the distance measurer 90 detects the distance to the main surface 3 of the substrate 2 while moving along the main surface 3 of the substrate 2. In this case, the shape of the substrate 2, such as the bending of the substrate 2, can be detected. The distance measurer 90 transmits a detection value to the controller 150.

In the process S104, the gas is jetted from the gas nozzle 40 disposed inside the processing vessel 20. In the process S104, the decompression mechanism 70 sucks in the gas inside the processing vessel 20, and the gas supply mechanism 60 supplies the gas to the gas nozzle 40. The composition of the gas supplied to the gas nozzle 40 (for example, the content C of the carbon dioxide gas) is regulated by the first flow rate regulating valve 65 and the second flow rate regulating valve 67. The supply pressure P of the gas supplied to the gas nozzle 40 is regulated by the pressure regulating valve 63.

In the process S105, a normal shock wave SW is formed as a result of the injection of the gas. Areas where the normal shock wave SW is formed are discontinuous, and there exits an area where the normal shock wave SW is not formed.

In the process S106, the normal shock wave SW is made to collide with the main surface 3 of the substrate 2. The wavefront of the normal shock wave SW may collide parallel to the main surface 3 of the substrate 2. In this case, the range in which the normal shock wave SW acts on the main surface 3 of the substrate 2 is large. Also, collapse of an irregularity pattern on the main surface 3 of the substrate 2 can be suppressed.

In the process S107, the particles are removed. In the process S107, due to the pressure of the normal shock wave SW, the particles are separated from the main surface 3 of the substrate 2.

The above-described processes S104 to S107 are repeated while changing the position on the substrate 2 where the normal shock wave SW is applied. This change in the position is carried out as the nozzle elevation driver 50 moves the gas nozzle 40 in the radial direction of the substrate 2 while the rotation driver 34 is rotating the substrate holder 30, for example. This allows the normal shock wave SW to collide with the entire main surface 3 of the substrate 2.

In one embodiment, by rotating the substrate holder 30 and moving it horizontally, the position on the substrate 2 to which the normal shock wave SW is applied is varied. As another example, the position on the substrate 2 to which the normal shock wave SW 16 is applied may be varied by moving the gas nozzle 40 in the X-axis and Y-axis directions in the state that the substrate holder 30 is fixed.

In the above-described processes S104 to S107, the controller 150 may control the distance G1 based on the shape of the substrate 2 detected in the process S103. In this case, even if the substrate 2 has suffered deformation such as bending, the normal shock wave SW can be made to collide with the entire main surface 3 of the substrate 2 in a uniform manner.

Further, in the above-described processes S104 to S107, the target value of the distance G1 may be reset. The controller 150 may reset the target value of the distance G1 based on the flow state of the gas jetted from the gas nozzle 40 while jetting the gas from the gas nozzle 40, and may control the distance G1 to the reset target value. In this case, even if the flow state of the gas changes during the injection of the gas from the gas nozzle 40, the target value of the distance G1 can be reset in real time so that the particle removing efficiency may be improved. The controller 150 may reset the target value of the distance G1 based on a pressure distribution of the gas or a mass flux density distribution of the gas calculated by a simulation using environmental parameters, the same as in the process S101, for example. As another example, the controller 150 may reset the target value of the distance G1 based on a Schlieren image obtained by the Schlieren device 80 while the gas is being jetted from the gas nozzle 40, the same as in the process S101, for example.

In the process S108, the substrate 2 is carried out from the inside of the processing vessel 20 to the outside of the processing vessel 20. In the process S108, the substrate holder 30 releases the holding of the substrate 2, and the transfer device receives the substrate 2 from the substrate holder 30 and carries out the received substrate 2 from the inside of the processing vessel 20 to the outside of the processing vessel 20. According to the substrate processing method described above, the target value of the distance G1 is set based on the flow state of the gas jetted from the gas nozzle 40, and at least one of the elevation driver 36 and the nozzle elevation driver 50 is controlled so that the distance G1 becomes the target value. This makes it possible to efficiently remove particles according to the processing environment.

Furthermore, the order of some of the processes S101 to S108 shown in FIG. 4 may be altered. By way of example, the process S101 may be performed after the process S102. In this case, the gas is injected from the gas nozzle 40 while the substrate 2 is held by the substrate holder 30. Therefore, in order to suppress the gas injected from the gas nozzle 40 from being jetted to the main surface 3 of the substrate 2, the gas receiver 100 may be moved to the gas receiving position under the injection opening 41. For another example, the process S103 may be performed in parallel with the processes S104 to S107.

Also, some of the processes S101 to S108 shown in FIG. 4 may not be performed. By way of example, when the target value of the distance G1 is set in the processes S104 to S107, the process S101 may not be performed. For another example, if the process S101 is performed, the target value of the distance G1 may not be reset in the processes S104 to S107. As a still another example, when the substrate 2 held by the substrate holder 30 has suffered no deformation such as bending, the process S103 may not be performed.

Here, it should be noted that the above-described exemplary embodiments are illustrative in all aspects and are not anyway limiting. The above-described exemplary embodiments may be omitted, replaced and modified in various ways without departing from the scope and the spirit of claims.

This international application claims priority to Japanese Patent Application No. 2022-139192, field on Sep. 1, 2022, which application is hereby incorporated by reference in their entirety.

### EXPLANATION OF CODES

2: Substrate
10: Substrate processing apparatus
20: Processing vessel
30: Substrate holder
40: Gas nozzle
36: Elevation driver
50: Nozzle elevation driver
150: Controller

1. A substrate processing apparatus, comprising:
a processing vessel;
a substrate holder disposed within the processing vessel, and configured to hold a substrate;
a gas nozzle configured to jet a gas to an inside of the processing vessel;
an adjusting driver configured to adjust a distance between the substrate held by the substrate holder and the gas nozzle; and
a controller having a processor and a memory with a computer readable program stored therein that upon execution of the computer readable program by the processor,
wherein the controller is configured to:
set a target value of the distance based on a flow state of the gas jetted from the gas nozzle, and
control the adjusting driver to adjust the substrate such that the distance becomes the target value.

2. The substrate processing apparatus of claim 1,
wherein the controller is further configured to calculate the flow state of the gas by a simulation using an environmental parameter that affects the flow state of the gas.

3. The substrate processing apparatus of claim 1, further comprising an imaging device.
wherein the controller is further configured to acquire the flow state of the gas by receiving an image from the imaging device of the gas jetted from the gas nozzle.

4. The substrate processing apparatus of claim 1,
wherein the controller is further configured to control the adjusting driver while jetting the gas from the gas nozzle onto the substrate held by the substrate holder.

5. The substrate processing apparatus of claim 1,
wherein the controller is further configured to control the adjusting driver in a state that the substrate is not held by the substrate holder.

6. The substrate processing apparatus of claim 1, further comprising:
a detector configured to detect a shape of the substrate held by the substrate holder,
wherein the controller is configured to adjust the adjusting driver based on the shape of the substrate detected by the detector.

7. The substrate processing apparatus of claim 1, wherein the gas includes a carbon dioxide gas and a hydrogen gas.

8. A substrate processing method, comprising:
holding a substrate with a substrate holder disposed within a processing vessel;
jetting a gas from a gas nozzle disposed within the processing vessel;
setting a target value of a distance between the substrate held by the substrate holder and the gas nozzle based on a flow state of the gas jetted from the gas nozzle; and
controlling the distance such that the distance becomes the target value.

9. The substrate processing method of claim 8,
wherein the setting of the target value comprises calculating the flow state of the gas by a simulation using an environmental parameter that affects the flow state of the gas.

10. The substrate processing method of claim 8,
wherein the setting of the target value comprises acquiring the flow state of the gas by imaging, by an imaging device, the gas jetted from the gas nozzle.

11. The substrate processing method of claim 8,
wherein the setting of the target value is performed while the gas is being jetted from the gas nozzle onto the substrate held by the substrate holder.

12. The substrate processing method of claim 8,
wherein the setting of the target value is performed in a state that the substrate is not held by the substrate holder.

13. The substrate processing method of claim 8, further comprising:
detecting a shape of the substrate held by the substrate holder,
wherein the controlling of the distance comprises controlling the distance based on the shape of the substrate detected in the detecting of the shape.

14. The substrate processing method of claim 8,
wherein the gas includes a carbon dioxide gas and a hydrogen gas.

15. A substrate processing apparatus, comprising:
a processing vessel;
a substrate holder disposed within the processing vessel, and configured to hold a substrate;
a gas nozzle configured to jet a gas to an inside of the processing vessel;
an adjusting driver configured to adjust a distance between the substrate held by the substrate holder and the gas nozzle;
a Schlieren device configured to generate an image of the gas jetted from the gas nozzle; and
a controller having a processor and a memory with a computer readable program stored therein that upon execution of the computer readable program by the processor,
wherein the controller is configured to:
set a target value of the distance based on a Schlieren image, the Schlieren image being obtained by the Schlieren device imaging the gas jetted from the gas nozzle, and
control the adjusting driver to adjust the substrate such that the distance becomes the target value to cause a removal of particles from the substrate.

16. The substrate processing apparatus of claim 15, the controller is configured to analyze the Schlieren image to identify a position of a normal shock wave, and set the target value of the distance based on the identified position of the normal shock wave.

17. The substrate processing apparatus of claim 16, further comprising:
a detector configured to detect a shape of the substrate held by the substrate holder,
wherein the controller is configured to adjust the adjusting driver based on the shape of the substrate detected by the detector.

18. The substrate processing apparatus of claim 15, further comprising a decompression mechanism including a suction pump, the decompression mechanism is configured to decompress the inside of the processing vessel.

19. The substrate processing apparatus of claim 15, wherein the gas includes a carbon dioxide gas and a hydrogen gas.

20. The substrate processing apparatus of claim 15, wherein the Schlieren device includes has a light source, a first Schlieren lens, a second Schlieren lens, a knife edge, and an imaging device, and
the first Schlieren lens is disposed opposite to the second Schlieren lens relative to the substrate.
